(19) United States
(12) Patent Application Publication
(10) Pub. No.: US 2021/0273196 A1
(43) Pub. Date: Sep. 2, 2021

(54) OLED DISPLAY PANEL

(71) Applicant: Shenzhen China Star Optoelectronics Semiconductor Display Technology Co., Ltd., Shenzhen (CN)

(72) Inventors: Chunhsiung Fang, Shenzhen (CN); Yuanchun Wu, Shenzhen (CN); Poyen Lu, Shenzhen (CN)

(21) Appl. No.: 16/099,180

(22) PCT Filed: Sep. 26, 2018
(86) PCT No.: PCT/CN2018/107775

§ 371 Date: Nov. 5, 2018

(30) Foreign Application Priority Data
Jul. 17, 2018 (CN) 201810785449.1

(51) Int. Cl. H01L 51/52; H01L 51/50; H01L 27/32

(52) U.S. Cl. CPC H01L 51/5218; H01L 51/5056; H01L 27/3246; H01L 51/5092; H01L 27/3218; H01L 51/5072

(57) ABSTRACT

The invention provides an organic light-emitting (OLED) display panel, comprising: a thin film transistor (TFT) array substrate comprising a metal oxide TFT, and a top-emitting OLED device disposed on the TFT array substrate; the top-emitting OLED device having a reflective anode of a multi-layer structure, and a bottom layer of the reflective anode being made of a hydrogen absorbing material. The OLED display panel of the present invention can reduce the diffusion of hydrogen atoms into the active layer of the metal oxide TFT, thereby improving the stability of the TFT.

### BACKGROUND OF THE INVENTION

### 1. Field of the Invention

The present invention relates to the field of display and, in particular, to the field of an organic light-emitting diode (OLED) display panel.

### 2. The Related Arts

An organic light-emitting diode (OLED) is an active light-emitting device. Compared with the current mainstream panel display technology, i.e, the thin film transistor liquid crystal display (TFT-LCD), OLED has the advantages of high contrast, wide viewing angle, low power consumption and thinner volume, and is expected to become the next generation panel display technology after LCD. Thus, OLED is one of the most attention-worthy technologies in panel display technology.

Compared with amorphous germanium (a-Si) TFTs, metal oxide TFTs (eg, IGZO, IGTO . . . ) have higher carrier mobility, low leakage current, and higher electrical stability, and thus are applied to the driving circuit of the OLED display. However, the oxygen atoms in the metal oxide TFT are easily reduced by hydrogen atoms to form oxygen defects, causing the electrical characteristics of the TFT to drift. To reduce the source of hydrogen atoms in the TFT structure, the dielectric layer uses the material of SiOx instead of SiNx film layer. According to different chemical vapor deposition (CVD) film forming conditions, the SiOx film still contains one to several tens of atomic percent (at %) hydrogen content. In the subsequent high temperature process or the local high temperature generated by the current during the operation of the display, the hydrogen atoms in the SiOx film have the opportunity to diffuse into the channel of the metal oxide TFT to cause the electrical characteristics of the TFT to shift and result in an abnormal display.

Referring to FIG. 1, FIG. 1 is a schematic cross-sectional view of a conventional top-emitting organic light-emitting display panel, which mainly comprises: a TFT array substrate comprising a TFT driving circuit; and a top-emitting OLED device disposed on the TFT array substrate, the TFT device forming the TFT driving circuit to drive the pixels can be a metal oxide TFT.

The TFT array substrate mainly comprises: a substrate 1, a buffer layer 2 disposed on the substrate 1, an active layer 3 disposed on the buffer layer 2, a gate insulating layer 4 disposed on the buffer layer 2 and the active layer 3, a gate metal layer 5 disposed on the gate insulating layer 4, an interlayer insulating layer 6 disposed on the buffer layer 2, the active layer 3, and the gate metal layer 5, a source/drain metal layer 7 disposed on the interlayer insulating layer 6, a passivation layer 8 disposed on the source/drain metal layer 7, and a planarization layer 9 disposed on the passivation layer 8; devices such as a switching TFT, a driving TFT, and a storage capacitor are formed by a patterned active layer 3, a gate metal layer 5, and a source/drain metal layer 7 to form the TFT driving circuit to drive the pixels. The interlayer insulating layer 6 and the passivation layer 8 are manufactured by using SiOx, as shown by the dotted arrow in FIG. 1, wherein hydrogen atoms have a chance to diffuse into the channel of the active layer 3 to cause shifting in the electrical characteristics of the TFT.

A top-emitting OLED device is prepared on the planarization layer 9, and the planarization layer 9 is disposed with vias for connecting to the TFT devices in the TFT array substrate. The top-emitting OLED device mainly comprises: a reflective anode 10 disposed on the planarization layer 9, a pixel definition layer 20 disposed on the planarization layer 9 and the reflective anode 10, an organic functional layer 21 disposed on the reflective anode 10 and the pixel definition layer 20, and a transparent cathode 22 disposed on the organic functional layer 21; when a suitable voltage is applied to the reflective anode 10 and the cathode 22, the organic functional layer 21 emits light. A general top-emitting organic light-emitting display panel adopts an ITO/Ag/ITO three-layer structure including an Indium Tin Oxide (ITO) layer 11, an Ag metal layer 12, and an ITO layer 13 as a reflective anode 10 to reflect light of the organic functional layer 21 to emit from the top.

### SUMMARY OF THE INVENTION

The primary object of the present invention is to provide an OLED display panel, able to reduce the diffusion of hydrogen atoms into the active layer of the metal oxide TFT.

To achieve the above objects, the present invention provides an OLED display panel, which comprises: a TFT array substrate comprising a metal oxide TFT, and a top-emitting OLED device disposed on the TFT array substrate; the top-emitting OLED device having a reflective anode of a multi-layer structure, and a bottom layer of the reflective anode being made of a hydrogen absorbing material.

Wherein, the hydrogen absorbing material is titanium metal.

Wherein, the reflective anode is a titanium metal/silver metal/ITO three-layer structure.

Wherein, the titanium metal layer has a thickness of 20 nm to 100 nm.

Wherein, the OLED device comprises red, green and blue OLED sub-pixels arranged side by side.

Wherein, the organic functional layer of the OLED sub-pixel comprises a hole injection layer, a hole transport layer, an organic light-emitting layer, an electron transport layer, and an electron injection layer.

Wherein, the OLED device comprises a white light OLED device.

Wherein, the organic functional layer of the white OLED device comprises a hole injection layer, a hole transport layer, an organic light-emitting layer, an electron transport layer, an electron injection layer, and a charge generation layer.

Wherein, the TFT array substrate comprises: a substrate, a buffer layer disposed on the substrate, an active layer disposed on the buffer layer, a gate insulating layer disposed on the buffer layer and the active layer, a gate metal layer disposed on the gate insulating layer, an interlayer insulating layer disposed on the buffer layer, the active layer, and the gate metal layer, a source/drain metal layer disposed on the interlayer insulating layer, a passivation layer disposed on the source/drain metal layer, and a planarization layer disposed on the passivation layer; the interlayer insulating layer and the passivation layer are prepared using SiOx.

Wherein, the top-emitting OLED device comprises: a reflective anode disposed on the TFT array substrate, a pixel definition layer disposed on the TFT array substrate and the reflective anode, and an organic functional layer disposed on the reflective anode and the pixel definition layer, and a cathode disposed on an organic functional layer.

In summary, the organic light-emitting display panel of the present invention can reduce the diffusion of hydrogen atoms into the active layer of the metal oxide TFT, thereby improving the stability of the TFT.

### BRIEF DESCRIPTION OF THE DRAWINGS

To make the technical solution of the embodiments according to the present invention, a brief description of the drawings that are necessary for the illustration of the embodiments will be given as follows. Apparently, the drawings described below show only example embodiments of the present invention and for those having ordinary skills in the art, other drawings may be easily obtained from these drawings without paying any creative effort.

FIG. 1 is a schematic cross-sectional view showing the structure of a traditional top-emitting OLED display panel.

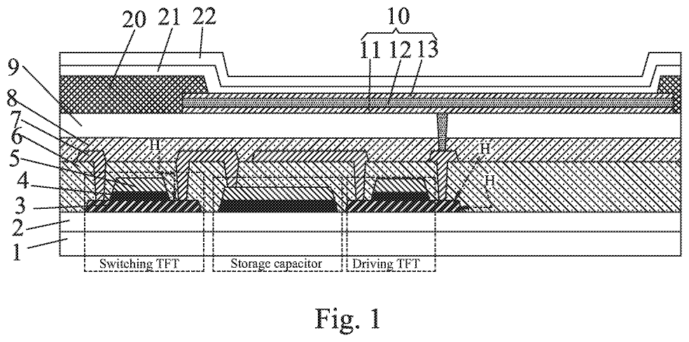

FIG. 2 is a schematic view showing the structure of a top-emitting OLED display panel according to an exemplary embodiment of the present invention.

### DETAILED DESCRIPTION OF THE PREFERRED EMBODIMENTS

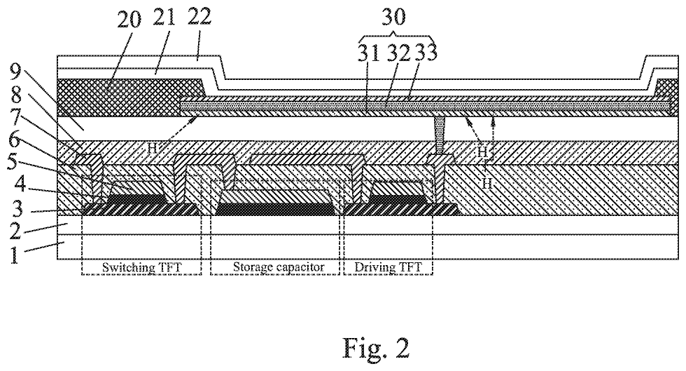

Refer to FIG. 2. FIG. 2 is a schematic view showing the structure of a top-emitting OLED display panel according to an exemplary embodiment of the present invention. The OLED display panel of the present invention provides comprises: a TFT array substrate comprising a metal oxide TFT, and a top-emitting OLED device disposed on the TFT array substrate; the top-emitting OLED device having a reflective anode 30 of a multi-layer structure, and a bottom layer of the reflective anode 30 being made of a hydrogen absorbing material. The hydrogen absorbing material is titanium metal.

In a preferred embodiment, the top-emitting OLED device is prepared on the planarization layer 9, and the planarization layer 9 is disposed with vias for connecting to the TFT devices in the TFT array substrate. The top-emitting OLED device mainly comprises: a reflective anode 30 disposed on the planarization layer 9, a pixel definition layer 20 disposed on the planarization layer 9 and the reflective anode 30, an organic functional layer 21 disposed on the reflective anode 30 and the pixel definition layer 20, and a transparent cathode 22 disposed on the organic functional layer 21; when a suitable voltage is applied to the reflective anode 30 and the cathode 22, the organic functional layer 21 emits light, and the reflective anode 30 reflects the light from the organic functional layer 21 to emit from the top. Specifically, the reflective anode 30 adopts an Ti/Ag/ITO three-layer structure including an titanium metal layer 31, an Ag metal layer 32, and an ITO layer 33. The titanium metal layer has a thickness of 20 nm to 100 nm.

In the preferred embodiment, the OLED device may comprise red, green and blue OLED sub-pixels arranged side by side. The organic functional layer of the OLED sub-pixel comprises, sequentially disposed on the reflective anode, a hole injection layer (HIL), a hole transport layer (HTL), an organic light-emitting layer (EML), an electron transport layer (ETL), and an electron injection layer (EIL). The OLED device may also be a white light OLED device, and the organic functional layer of the white OLED device comprises a hole injection layer, a hole transport layer, an organic light-emitting layer, an electron transport layer, an electron injection layer, and a charge generation layer (CGL).

In the preferred embodiment, the TFT array substrate comprises: a substrate 1, a buffer layer 2 disposed on the substrate 1, an active layer 3 disposed on the buffer layer 2, the active layer 3 forming a channel in the middle and having two ends connected respectively to a source and a drain of a TFT, a gate insulating layer 4 disposed on the buffer layer 2 and the active layer 3, a gate metal layer 5 disposed on the gate insulating layer 4, an interlayer insulating layer 6 disposed on the buffer layer 2, the active layer 3, and the gate metal layer 5, a source/drain metal layer 7 disposed on the interlayer insulating layer 6, a passivation layer 8 disposed on the source/drain metal layer 7, and a planarization layer 9 disposed on the passivation layer 8; devices such as a switching TFT, a driving TFT, and a storage capacitor are formed by a patterned active layer 3, a gate metal layer 5, and a source/drain metal layer 7 to form the TFT driving circuit to drive the pixels, wherein the interlayer insulating layer 6 and the passivation layer 8 are prepared using SiOx.

The present invention replaces the ITO at the bottom of the existing reflective anode with titanium metal, and the overall reflective anode structure is Ti/Ag/ITO. Since titanium is a hydrogen absorbing material, hydrogen atoms can be stored in the interstitial atom of titanium or react with titanium to form a hydrogenated state (TiHx; x=1.5 to 1.99). When a hydrogen atom enters the titanium metal, a higher activation energy is required to be released from the titanium metal. Therefore, when the hydrogen atoms in the interlayer insulating layer or the passivation layer start to diffuse due to the high temperature, as shown by the dotted arrow in FIG. 2, part of the hydrogen atoms enter the titanium metal. As the area of the reflective anode layout occupies most of the display area, the titanium metal can effectively absorb hydrogen atoms, reduce the diffusion of hydrogen atoms into the active layer of the metal oxide TFT, and thereby improve the stability of the TFT.

In summary, the organic light-emitting display panel of the present invention can reduce the diffusion of hydrogen atoms into the active layer of the metal oxide TFT, thereby improving the stability of the TFT.

It should be noted that each of the embodiments in this specification is described in a progressive manner, each of which is primarily described in connection with other embodiments with emphasis on the difference parts, and the same or similar parts may be seen from each other. For the device embodiment, since it is substantially similar to the method embodiment, the description is relatively simple and the relevant description may be described in part of the method embodiment.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the clams of the present invention.

1. An organic light-emitting diode (OLED) array substrate, comprising: a thin film transistor (TFT) array substrate comprising a metal oxide TFT, and a top-emitting OLED device disposed on the TFT array substrate; the top-emitting OLED device having a reflective anode of a multi-layer structure, and a bottom layer of the reflective anode being made of a hydrogen absorbing material,
wherein the TFT array substrate comprises at least one layer made of SiOx and wherein the multi-layer structure of the reflective anode is disposed above the at least one layer of SiOx and comprises multiple layers of materials, including the bottom layer made of the hydrogen absorbing material and at least one remaining layer, the bottom layer of the hydrogen absorbing material being arranged on an underside of the multi-layer structure and located below the at least one remaining layer so as to be closer to the at least one layer of SiOx than the at least one remaining layer of the multi-layer structure of the reflective anode.

2. The OLED array substrate as claimed in claim 1, wherein the hydrogen absorbing material is titanium metal.

3. The OLED array substrate as claimed in claim 1, wherein the reflective anode is a titanium metal/silver metal/ITO three-layer structure.

4. The OLED array substrate as claimed in claim 3, wherein the titanium metal layer has a thickness of 20nm to 100nm.

5. The OLED array substrate as claimed in claim 1, wherein the OLED device comprises red, green and blue OLED sub-pixels arranged side by side.

6. The OLED array substrate as claimed in claim 5, wherein the organic functional layer of the OLED sub-pixel comprises a hole injection layer, a hole transport layer, an organic light-emitting layer, an electron transport layer, and an electron injection layer.

7. The OLED array substrate as claimed in claim 1, wherein the OLED device comprises a white light OLED device.

8. The OLED array substrate as claimed in claim 7, wherein the organic functional layer of the white OLED device comprises a hole injection layer, a hole transport layer, an organic light-emitting layer, an electron transport layer, an electron injection layer, and a charge generation layer.

9. The OLED array substrate as claimed in claim 1, wherein the TFT array substrate comprises: a substrate, a buffer layer disposed on the substrate, an active layer disposed on the buffer layer, a gate insulating layer disposed on the buffer layer and the active layer, a gate metal layer disposed on the gate insulating layer, an interlayer insulating layer disposed on the buffer layer, the active layer, and the gate metal layer, a source/drain metal layer disposed on the interlayer insulating layer, a passivation layer disposed on the source/drain metal layer, and a planarization layer disposed on the passivation layer; the interlayer insulating layer and the passivation layer are prepared using SiOx.

10. The OLED array substrate as claimed in claim 1, wherein the top-emitting OLED device comprises: a reflective anode disposed on the TFT array substrate, a pixel definition layer disposed on the TFT array substrate and the reflective anode, and an organic functional layer disposed on the reflective anode and the pixel definition layer, and a cathode disposed on an organic functional layer.
